(19) United States
(12) Patent Application Publication
(10) Pub. No.: US 2022/0025544 A1
(43) Pub. Date: Jan. 27, 2022

(54) SYSTEMS AND METHODS FOR LOW PRESSURE DIAMOND GROWTH WITHOUT PLASMA INCLUDING SEEDING GROWTH

(71) Applicants: The Texas A&M University System, College Station, TX (US); King Abdulaziz City for Science and Technology, Riyadh (SA); Ulm University, Ulm (DE); Max-Planck Institute for Polymer Research, Mainz (DE)

(72) Inventors: Philip R. Hemmer, College Station, TX (US); Masfer Hassan A. Alkahtani, Riyadh (SA); Fedor Jelezko, Ulm (DE); Todd Zapata, Mainz (DE); Tanja Weil, Mainz (DE); Isaac V. Rampersaud, Columbus, OH (US)

(21) Appl. No.: 17/290,701

(22) PCT Filed: Nov. 1, 2019
(86) PCT No.: PCT/US19/59368

§ 371 Date: Apr. 30, 2021

Related U.S. Application Data
(60) Provisional application No. 62/755,239, filed on Nov. 2, 2018.

(51) Int. Cl. C30B 29/04; B01J 3/06; C01B 32/26; C01B 32/15; C09K 11/06

(52) U.S. Cl. CPC C30B 29/04; B01J 3/06; C01B 32/26; C01B 32/15; B82Y 40/00; C01P 2006/60; C01P 2002/30; C01P 2004/64; C09K 11/06

(57) ABSTRACT

A method for low-pressure diamond growth includes heating a composition comprising a diamond growth seed and a source of reactive carbon to a temperature below 800° C., wherein the heating takes place under low pressure. Responsive to the heating, growing diamonds from the composition.

### CROSS-REFERENCE TO RELATED APPLICATIONS

This patent application claims priority from, and incorporates by reference the entire disclosure of U.S. Provisional Patent Application No. 62/755,239 filed on Nov. 2, 2018.

### BACKGROUND

Graphite is known to be the most stable form of carbon at atmospheric pressure. However, diamond is metastable and does not easily convert to graphite under ambient temperature and pressure. Hence, there is no reason in principle why diamond should not be able to grow under quasi-equilibrium conditions at low pressure. Nonetheless, it was long assumed that diamond could only be grown under extreme growth conditions that included high pressure. This view was first challenged when it was discovered that high pressure is not required if a suitable plasma is present, for example chemical vapor deposition (CVD). Even without plasma, atomistic models predicted that ultra-small nanodiamonds could be more stable than graphite at atmospheric pressure, provided they are hydrogen-terminated and smaller than ˜10 nm in size. Experimental verification using carbon implanted infused quartz gave a diamond a stability size limit of ˜7 nm for cubic diamond and ˜13 nm for n-diamond. Many other experiments discuss nanodiamonds formed in meteors, molten lithium chloride, petroleum, detonation soot, candle flames, and micro-plasma. However, none of these other experiments give a clear recipe for scaling low pressure diamond growth to arbitrarily large sizes with high crystal quality and purity.

Diamonds have also recently attracted special attention in several other important application areas due to their optical properties, surface chemistry, and biocompatibility. These applications include quantum information, advanced bio-sensing including drug delivery, hyper-polarized magnetic resonance imaging (MRI), and even nanoscale imaging down to the single protein level, and advanced materials diagnostics, especially for magnetic materials and superconductors. For the more demanding of these applications, considerable effort has been focused on growing or synthesizing nanodiamonds with properties comparable to bulk diamonds. Diamonds are known for their extreme hardness, exceptional chemical and biological inertness, and very high heat conductivity. As a result, they have numerous industrial applications. The most common application is to abrasives, like cutting tools and polishing grit. They are also used as heat sinks for electronics, chemical and biological resistant coatings. Boron doped diamonds that are conducting are even used as electrochemical electrodes for use in harsh chemicals.

Fluorescent nanodiamonds (FNDs) are superior to standard fluorescent markers (e.g., organic dyes and quantum dots) due to their exceptional optical properties, extraordinary photostability, and biocompatibility. These properties make fluorescent nanodiamonds candidate materials for many applications that can include, but are not limited to, quantum information, advanced bio-sensing, and materials research. Among the fluorescent color centers in diamonds, a nitrogen-vacancy (NV) color center is a good candidate for most of the aforementioned applications. It has been reported that 100 nm fluorescent nanodiamonds containing approximately 1000 NVs/particles are ˜10× brighter than a conventional dye (e.g., Atto 532). However, due to probabilistic placement of color centers in nanodiamond crystals, the brightness of fluorescent nanodiamonds drops with decreasing particle size. This problem is a direct consequence of the way diamond color centers are produced.

### SUMMARY OF THE INVENTION

In an embodiment, a method for low-pressure diamond growth includes heating a composition including a source of reactive carbon to a temperature, where the heating takes place under a pressure, and responsive to the heating, growing diamonds from the composition.

In another embodiment, a method for low-pressure diamond growth includes heating a composition that includes a source of reactive carbon to a temperature below 800° C. where diamond does not spontaneously convert to graphite, where the heating takes place under a pressure below 1 GPa where diamond is not the most stable form of carbon and responsive to the heating, growing diamonds from the composition.

In another embodiment, a method for low-pressure diamond growth includes heating a composition including a source of reactive carbon to a temperature, where the heating takes place under vacuum, the reactive carbon source is a paraffin, heptamethylnonane, tetracosane, heptamethylnonane/tetracosane, any long-chain alkene that produce methyl radicals, ethyl radicals, alkyl radicals, or combinations thereof.

In another embodiment, a method for low-pressure diamond growth includes heating a composition including a source of reactive carbon to a temperature, where the heating takes place under a pressure, and the composition further includes a diamond growth seed where the diamond growth seed is aza-admantane, diaza-admantane, an adamantane derivative, an adamantane-like derivative, tetrakis(trimethylsilyl)silane, any diamond-like molecule, any hydrogen-terminated diamond, or combinations thereof, and the composition also includes a catalyst, where the catalyst is graphene, graphite flakes, or combinations thereof and responsive to the heating, growing diamonds from the composition.

In an additional embodiment, a system for low-pressure diamond growth includes a chamber operable to be heated under a desired pressure, an optional substrate or crucible residing within the chamber, and a composition on the optional substrate or in the crucible or in the chamber that includes a reactive carbon.

In a further embodiment, a system for low-pressure diamond growth includes a chamber operable to be heated under a desired pressure, where the desired pressure is vacuum pressure, an optional substrate or other container residing within the chamber, and a composition on the optional substrate or in the other container or the chamber. Further the composition includes a source of reactive carbon, the reactive carbon source is a paraffin, heptamethylnonane, tetracosane, heptamethylnonane/tetracosane, any long-chain alkene that produce methyl radicals, ethyl radicals, alkyl radicals, or combinations thereof, a diamond-like growth seed molecule where the diamond growth seed is aza-admantane, diaza-admantane, an adamantane derivative, an adamantane-like derivative, tetrakis(trimethylsilyl)silane, any diamond-like molecule, any hydrogen-terminated diamond, or combinations thereof, a catalyst where the catalyst is graphene, graphite flakes, or combinations thereof, and a solubility enhancer for the diamond-like seed molecule including halogenated hydrocarbon, a graphite suppressant such as hydrazine derivative, or combinations thereof, responsive to the heating, growing diamonds from the composition.

In an embodiment, a method for low-pressure diamond growth includes heating a composition comprising a diamond growth seed and a source of reactive carbon to a temperature below 800° C., wherein the heating takes place under low pressure. Responsive to the heating, growing diamonds from the composition.

In an embodiment, a method for low-pressure diamond growth by heating a composition that includes a reactive carbon source, a diamond growth seed, and a catalyst to a temperature below 800° C. Responsive to the heating, diamonds grow from the composition. In embodiments, the heating takes place under vacuum. In embodiments, the reactive carbon source is a paraffin, heptamethylnonane, tetracosane, heptamethylnonane/tetracosane, any long-chain alkene that produce methyl radicals, ethyl radicals, alkyl radicals, or combinations thereof. In embodiments, the diamond growth seed is aza-admantane, diaza-admantane, an adamantane derivative, an adamantane-like derivative, tetrakis(trimethylsilyl)silane, any diamond-like molecule, any hydrogen-terminated diamond, or combinations thereof. In embodiments, the catalyst is graphene, graphite flakes, or combinations thereof.

In an embodiment, a system for low-pressure diamond growth includes a chamber operable to be heated under a vacuum pressure and a composition disposed on a substrate. In embodiments, the composition includes a source of reactive carbon, the reactive carbon source is a paraffin, heptamethylnonane, tetracosane, heptamethylnonane/tetracosane, any long-chain alkene that produce methyl radicals, ethyl radicals, alkyl radicals, or combinations thereof, a diamond-like seed molecule where the diamond growth seed is aza-admantane, diaza-admantane, an adamantane derivative, an adamantane-like derivative, tetrakis(trimethylsilyl)silane, any diamond-like molecule, any hydrogen-terminated diamond, or combinations thereof. In embodiments, the composition includes a catalyst where the catalyst is graphene, graphite flakes, or combinations thereof. In embodiments, the composition comprises a solubility enhancer for the diamond-like seed molecule including halogenated hydrocarbon, a graphite suppressant such as hydrazine derivative, or combinations thereof.

### BRIEF DESCRIPTION OF THE DRAWINGS

A more complete understanding of the subject matter of the present disclosure may be obtained by reference to the following Detailed Description when taken in conjunction with the accompanying Drawings wherein:

FIG. 1(a) is an illustration of a process for growing nanodiamonds on a TEM grid in vacuum;

FIG. 1(b) is an illustration of a process for seeded growth of nanodiamonds on a TEM grid in vacuum;

FIG. 2(a) is an illustration of a process for seeded growth of fluorescent nanodiamonds on a quartz substrate;

FIG. 2(b) is a graph showing an optical spectrum of grown nanodiamonds;

FIG. 3(a) is graph showing a fluorescence spectrum of the NV center in nanodiamonds grown around 2-azaadamantane hydrochloride organic molecule seeds in vacuum at 800° C.;

FIG. 3(b) is a graph showing the corresponding ODMR spectrum of the NV center with contrast at 4.7% under green excitation (532 nm);

FIG. 3(c) is a graph showing the photoluminescence spectrum of H3 color center (solid line) in nanodiamonds grown around 5,7-dimethyl-1,3-diazaadamantane in vacuum at 800° C. under blue excitation (471 nm);

FIG. 3(d) is a graph showing an emission spectrum of the NV and SiV centers in nanodiamonds grown around 2-azaadamantane hydrochloride seed and tetrakis(trimethylsilyl)silane seed;

FIG. 4 is a graph illustrating a growth process of nanodiamonds having two different growth rates;

FIG. 5(a) illustrates a process of irradiation of nanodiamonds on a TEM grid;

FIG. 5(b) is a graph showing clear NV center fluorescence emission of a representative NV center after irradiation of nanodiamonds;

FIG. 5(c) is a graph showing NV center in diamond corresponding ODMR spectrum centered at 2875 MHz with 3.6% contrast;

FIG. 6(a) illustrates a process using a custom vacuum growth chamber containing diamond growth mixture placed on a substrate comprising quartz and silicon;

FIG. 6(b) is a graph showing an optical spectrum of grown nanodiamonds;

FIG. 6(c) is a graph showing a clear NV center fluorescence emission of a representative NV center after irradiation of nanodiamond;

FIG. 6(d) is a graph showing ODMR spectrum centered at 2875 MHz with 6.5% contrast;

FIG. 7(a) is a graph showing Rabi oscillations between mₛ=0 and mₛ=±1 states;

FIG. 7(b) is a graph showing longitudinal relaxation time T₁ of the NV center;

FIG. 7(c) is a graph showing NV center spin coherence time (T₂);

FIG. 7(d) is a graph showing ODMR spectrum splitting due to different magnetic field values;

FIG. 8(a) illustrates a process for nanodiamond growth at atmospheric pressure;

FIG. 8(b) illustrates a diamond growth apparatus;

FIG. 8(c) is a graph showing an optical spectrum of grown nanodiamonds;

FIG. 9(a) illustrates a process for irradiation and annealing of nanodiamonds;

FIG. 9(b) is a graph showing NV fluorescence emission of a representative nanodiamond after irradiation and annealing; and

FIG. 9(c) is a graph showing a splitting-free ODMR spectrum centered at 2875 MHz with 9.4% contrast.

### DETAILED DESCRIPTION

It is to be understood that the following disclosure provides many different embodiments, or examples, for implementing different features of various embodiments. Specific examples of components and arrangements are described below to simplify the disclosure. These are, of course, merely examples and are not intended to be limiting. The section headings used herein are for organizational purposes and are not to be construed as limiting the subject matter described.

Most diamonds are produced using growth techniques that operate at harsh conditions of pressure, temperature, or combinations thereof. In addition, large-area diamonds are produced under aggressive plasma conditions by a process known as plasma-enhanced chemical vapor deposition (PECVD), sometimes abbreviated as CVD.

Most fluorescent nanodiamonds are produced by harsh processing of larger diamonds grown by other techniques, for example mechanical pulverizing of high pressure and high temperature (HPHT) grown diamonds or CVD diamonds. In addition, nanodiamonds are produced by the detonation of explosives, and non-detonation shock wave techniques, such as, laser ablation and ultrasound, and other numerous techniques. These existing nanodiamond fabrication techniques produce material that is not close to the quality of bulk diamonds, and this often leads to photostability problems for sizes less than 10 nm, and additional sensitivity problems for magnetic-sensitive NV centers.

A direct growth of fluorescent nanodiamonds from organic molecules using HPHT was performed at a pressure of approximately 8 GPa and a growth temperatures ranging from approximately 900° C. to 1500° C. or higher, at which temperature all the organic molecules had decomposed, following previously reported techniques.

Recently, small fluorescent nanodiamonds were grown from organic molecules (e.g., adamantane derivatives) at a moderate growth temperature of approximately 550° C. under static pressure using a seeded growth technique.

Additionally, growth of high-quality nanodiamonds around diamondoid seed molecules to provide for higher quality nanodiamonds using CVD techniques have been attempted. Recently, the growth temperature has been reduced to well below the diamondoid decomposition temperature seeking to improve yield (fraction of diamondoids producing diamonds). However, the yield is still extremely small (e.g., isolated nanodiamonds separated by microns compared to seed layers with sub-nanometer-scale seed separations).

Another approach to grow small nanodiamonds at ambient condition involves using micro-plasma growth techniques. It has been shown that color centers can be probabilistically formed in nanodiamonds during and/or after mixtures of gases and ethanol/methanol vapors that are being continuously introduced and dissociated in the micro-plasma diamond growth system. Due to a continuous dissociation of chemical bonds of precursors, plasma growth techniques are not an ideal way to implement seeded growth techniques, for example using diamond-like organic molecules that contain selected atoms to produce desired color centers at the center of nanodiamonds.

Furthermore, it has been also reported that nanodiamonds can be grown from carbon nanoparticles by a simple heating at atmospheric pressure, far less severe conditions than conventional processes, however, only small amounts of nanodiamonds are produced and are covered by graphite.

Diamond and diamond-like carbon has previously been grown at 1000° C. from a decomposed polymer in an inert atmosphere, but no high-quality single-crystal diamond is produced.

Prior work shows that nanodiamonds can be grown inside molten quartz in an unpressurized hydrogen atmosphere up to 15 nm, but converts to graphite above this size.

High quality nanodiamonds have been produced by plasma-based CVD techniques, which operate well below atmospheric pressure, but cannot be scaled to large volumes of material because they involve growth on a surface.

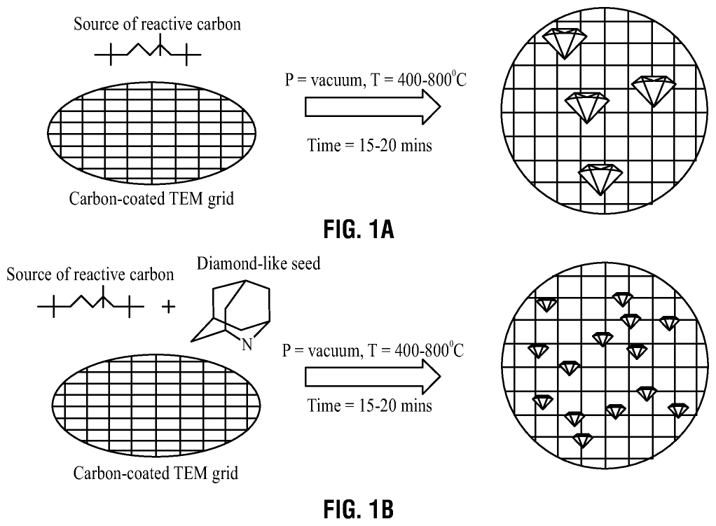

To overcome these limitations, growing conditions at lower temperatures and pressures, without plasma, can be used. In the present disclosure, we show that the nano-scale size limits do not apply to low-pressure diamond growth, even with no plasma present. In particular, we grow diamond of sufficiently large size, up to 200 nm, where the bulk diamond properties should apply, and hence in principle there is no size limit. The present disclosure provides systems and methods in which high quality and graphite-free nanodiamonds are produced in pressures as low as vacuum at moderate temperatures, as illustrated in FIG. 1. FIG. 1(a) shows an illustration of the concept of nanodiamond growth on a carbon TEM grid in vacuum. The growth process includes adding a carbon source to the grid, capable of producing reactive carbon, such as methyl and/or ethyl radicals, and then heating at vacuum. The reactive carbon can be supplied by cracking a hydrocarbon.

Moreover, seeded fluorescent nanodiamonds are also produced using the systems and methods disclosed herein, providing several applications for small and photostable fluorescent nanodiamonds. A diamond-like seed molecule is chosen that has specific atoms arranged in the approximate locations needed to form a color center of interest. FIG. 1(b) shows an illustration of the concept of nanodiamond growth on a carbon TEM grid in vacuum. Again, the growth process includes adding a source capable of producing reactive carbon, such as methyl and/or ethyl radicals, and then heating at vacuum. Again the reactive carbon can be supplied by cracking a hydrocarbon that is chosen such that it decomposes at a much lower temperature than the diamond-like seed molecule.

In one aspect, the present disclosure relates to the growth of diamonds at lower pressures than can currently be achieved without the use of plasma. Pressures, as disclosed herein, can go down to zero (i.e., a vacuum), however, other pressures also have great application potential. These pressures can include, but are not limited to, atmospheric pressure and up to the range achievable by low-cost autoclaves (e.g., 0.7 GPa), or lower. Another aspect of the present disclosure relates to the ability to perform molecule-seeded growth at low pressure. Seeded growth can also be extended to include any diamond seed with hydrogen termination, even those much larger than molecules. The systems and methods presented herein allow for a way to grow diamonds at low pressure. The systems and methods disclosed herein are similar to prior growth methods at low temperatures using organic precursors, except, notably, high pressure is no longer required, and the diamond growth will work over a wider range of temperatures (e.g., around 200-800° C.), but still at low pressure (e.g., down to vacuum pressure).

In some embodiments, the systems and methods presented herein relate to techniques to grow both single crystal and polycrystalline diamonds in a vacuum or inert atmosphere, starting from an appropriate source that decomposes to produce reactive carbon (e.g., hydrocarbons) where the final size of the grown diamonds range from a few nanometers up to microns. In some embodiments, the final size of the grown diamonds can be larger than microns.

In some embodiments, the systems and methods presented herein relate to techniques to grow diamonds in vacuum or inert atmosphere, at temperatures below 1000° C., for example, approximately 400-500° C. In some embodiments, the growth temperature is below 800° C. In some embodiments, the growth temperature is lower than 400° C.

In some embodiments, the systems and methods presented herein relate to techniques to seed the growth of diamonds in a vacuum or inert atmosphere, where the seed molecule determines the color center produced. In some embodiments, the seed molecules can be adamantane derivatives or adamantane-like seeds. In various embodiments, the seed molecules have one or more nitrogen atoms in the cage like aza-adamantane. In various embodiments, the seed molecules have other atoms, like silicon, germanium, tin, or any other atom, or isotope that can be either substituted for a carbon in the diamondoid or covalently attached to it. In various embodiments, the seed molecules are larger diamondoids or diamondoid derivatives with other atoms either incorporated into the structure or attached to it.

In some embodiments, if a silicon-containing compound is utilized as a seed molecule, the silicon-containing compound may decompose to provide elemental silicon which could be incorporated at lower growth temperatures under low-pressure conditions. In various embodiments, seed molecules can be combined with other compounds, seed molecules, or combinations thereof. In some embodiments, the seed molecules can be 13C-type seeds. In some embodiments, for seeded growth, diamond-like molecules that have any atom that can be covalently bonded as to survive at the initial growth temperature can be utilized for seed molecules. In various embodiments, the seed can be larger than a molecule, such as a nanodiamond or bulk diamond whose surface is hydrogen terminated. In various embodiments, the seed can be a hydrogen-terminated nanodiamond or bulk diamond whose surface is additionally functionalized at various locations with other non-carbon atoms.

In some embodiments, a reactive carbon source can be utilized to initiate diamond growth either on a substrate or in a container. In some embodiments, no substrate is required. In some embodiments, the substrate can be a carbon substrate or a quartz substrate. In some embodiments, the reactive carbon source can be a hydrocarbon like paraffin, heptamethylnonane, tetracosane, heptamethylnonane/tetracosane, or combinations thereof that can produce methyl radicals, ethyl radicals, alkyl radicals, or other radicals. In some embodiments, the reactive carbon source can be a halogenated hydrocarbon that can become reactive at much lower temperatures than regular hydrocarbons, and can grow diamonds by direct substitution of methyl or ethyl groups or by low-temperature radical formation, or by UV assisted decomposition. In various embodiments, any compound that suppresses evaporation of the growth material under vacuum can be utilized in conjunction with the system and methods provided herein. In various embodiments, the compound that suppresses evaporation can include graphene, or graphite or amorphous carbon flakes. In various embodiments, graphene and/or graphite flakes may not be needed, for example, in an autoclave. In other embodiments, halogenated hydrocarbons can be utilized to suppress graphite formation at high growth temperatures by decomposing to produce acids that add across carbon double bonds that would otherwise serve as graphite precursors, leaving only carbon single bonds. In other embodiments, hydrazine derivatives can be utilized to suppress graphite formation at high growth temperatures by decomposing to produce nitrogen gas that can isolate growth material from the walls of metal pressure chambers.

In some embodiments, the reactive carbon source can be any long-chain alkane, alkene, alkyne, provided the majority of the carbon bonds are saturated (i.e. single bonds). In these embodiments, the long-chain alkane should boil at a high enough temperature that the vapor pressure does not exceed the capability of the autoclave, or in the case of vacuum growth, that enough material remains in the vacuum reaction vessel at growth temperature, where it is understood that the evaporation can be suppressed by the catalyst consisting carbon materials like amorphous carbon, graphite or graphene flakes or powders. In various embodiments, in addition to the reactive carbon source, the growth mix can contain seed molecules. In these embodiments, a solubility-enhancing chemical such as, for example, halogenated hydrocarbon or any other strong solvent can be utilized. The solvent itself can also be capable of decomposing to produce reactive carbon to grow diamonds.

Currently, diamonds require pressures of at least 10,000 atm (˜1 GPa) to grow. In some embodiments, the vacuum disclosed in the various techniques presented herein can be replaced by an inert gas at pressures up to 10 s of atmospheres, which are currently accessible via most commercial autoclaves or hydrothermal-type reactors, and up to 100 s of atmospheres which are currently accessible by more-specialized commercial heating chambers.

In some embodiments, selective growth of different forms of diamond can be obtained by adjusting growth conditions, such as, for example, temperature and pressure. In various embodiments, the systems and methods of the present disclosure can utilize growth pressures ranging from a vacuum to about 1 GPa. In further embodiments, the growth pressure can range from about 1 atm to about 2 atm. In some embodiments, the growth pressure can be below 1 atm.

In some embodiments, the diamond growth techniques disclosed herein can be implemented on a stovetop, which dramatically reduces the cost to produce diamonds. As such, anyone with a heater and a growth chamber with an inert atmosphere can grow diamonds in large quantities. Furthermore, in some embodiments, the grown diamonds can be of the same or higher quality than most diamonds currently grown using high-pressure techniques. In various embodiments, the seeded growth techniques presented herein can operate at lower growth temperatures and lead to higher quality diamonds.

In some embodiments, low pressure growth can be utilized to enlarge the size of nanodiamonds previously grown at high pressure. In various embodiments the nanodiamond enlargement can be assisted by a carbon material that suppresses evaporation of the growth material.

In various embodiments, various growth mixes can be analyzed to identify constituents that are primarily responsible for diamond growth. In this manner, the identification of the primary constituents can allow for optimization of diamond growth.

In further embodiments, the carbon film can react with the reactive carbon source (e.g., paraffin) to increase the boiling, or sublimation, point of the latter, such that enough starting material survives at the growth temperature, even under vacuum, to grow larger diamonds.

In some embodiments, diamond growth can be conducted in an autoclave, made for example, with titanium or a superalloy to resist failure at high temperatures, with or without a growth seed at a temperature around 500° C. (e.g., utilizing tetracosane with a vapor pressure of just over 100 psi). In this embodiment, a custom liner in the autoclave can be utilized to eliminate decomposing of the liner when the temperature exceeds 260° C. In this embodiment, the custom liner can be OFHC copper or other material that withstands higher temperature and resists reaction with the diamonds or growth mixture.

In some embodiments, the diamonds produced by the systems and method disclosed herein can be utilized to grow diamond-like compounds such as silicon carbide, boron nitride, or other such diamond-like compounds. In these embodiments, the diamond-like seed molecules composed of these materials can be synthesized to form such diamond-like compounds.

In some embodiments, diamonds are grown at atmospheric pressure and at temperatures accessible on a chemical lab bench, and in some cases on a stovetop of the type used for cooking. In some experiments, the size of the grown nanodiamonds is ˜30 nm. However, much larger diamonds can be grown, as evidenced by growth of larger diamonds in vacuum. To improve yield, grow is done around diamond-like template, or seed molecule. The grown nanocrystals can be made fluorescent by ion implantation and annealing. In particular nitrogen-vacancy (NV) color centers were created by this process. These experiments not only validate that the grown crystals are in fact cubic diamond, but also act as a sensitive probe of local crystal quality. Because of its simplicity, scalability, and ability to grow high-quality diamond, this novel growth technique holds promise for virtually all applications of industrial diamonds including more demanding applications to quantum information and biology.

### WORKING EXAMPLES

Reference will now be made to more specific embodiments of the present disclosure and data that provides support for such embodiments. However, it should be noted that the disclosure below is for illustrative purposes only and is not intended to limit the scope of the claimed subject matter in any way.

### Working Example 1

A diamond growth mixture of organic seed molecule (aza-adamantane) and a reactive carbon source (heptamethylnonane/tetracosane) was prepared and dropped on a transmission electron microscope (TEM) lacy-carbon grid as shown in FIG. 1(b). The TEM grid was first annealed at 300° C. in air to remove most of the volatile components, and was placed on a TEM heating stage attached to a TEM microscope. By increasing the heating stage temperature up to 800° C. for 10-15 minutes, well-crystalline nanoparticles were observed. TEM diffraction of these nanoparticles shows diamond spacing of (111) cubic or n-diamond. Repeating the experiment without the seed molecules gives fewer but larger diamonds as shown in FIG. 1(a).

Next, growth-temperature dependence was investigated as diamonds growing in the TEM were observed. As 500° C. is on the edge of stability for many seed molecules, the temperature first started at 400° C. for 1 hour. The temperature was then raised to 500° C., and subsequently raised to 800° C. At 400° C. for 1 hour, several diamonds growing with particle size below 20 nm were produced. TEM imaging of the seeded nanodiamonds grown in vacuum at 400° C. illustrated a corresponding TEM diffraction pattern that showing a mixture of cubic and n-diamonds. Some diamonds observed during growth started as a cubic morphology. However, as the temperature increased they grew into ellipsoidal shapes. Low and high magnification images of seeded nanodiamonds grown on a TEM grid in vacuum at 800° C. for 10 minutes were collected. TEM diffraction analysis of the product showed a mixture of graphite crystals, a small amount of cubic diamonds that have diamond spacing of (111), but mostly n-diamonds. A diffraction peak near the location of the forbidden (200) diffraction was observed, indicating a structure similar to n-diamond. No spacing larger than (200) was observed in these crystals.

Next, the temperature was increased to 600° C., and subsequently raised to 800° C., and the diamonds grew faster with increasing temperature until the growth material was used up, indicating diamond growth by self-seeding on the TEM grid. Well-crystalline nanodiamonds were produced and the size increased until around 100 nm was observed. The size of each individual nanodiamond crystal increases until the growth material around it was consumed. The presence of the nanodiamond was confirmed by the TEM diffraction characterizations.

Toward the end of the characterization, at 800° C., a large number of very small diamonds appeared. It is contemplated that the size is related to the number, as one would expect if a fixed amount of growth material was being consumed. It was thought, that, perhaps the carbon membrane of the TEM grid was somehow catalyzing diamond growth. To verify this, growing diamonds on TEM silicon grids was tried. However, no diamonds, at least large enough to see through the polycrystalline silicon membranes, were observed. Growth mixes were also placed on a silicon chip and heated, first in air to 300° C. to remove volatiles, then in vacuum to 800° C. No diamonds were formed, indicating that the carbon membrane leads to diamond growth in vacuum.

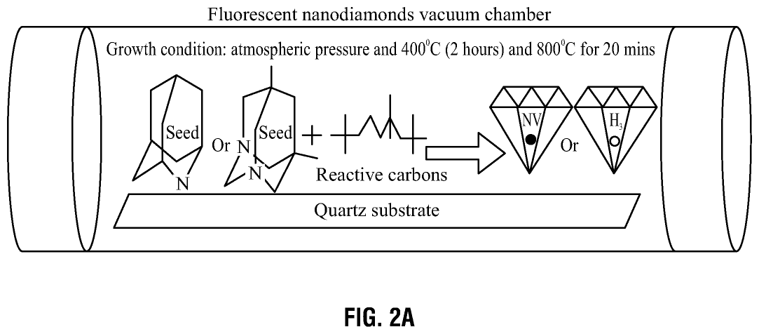

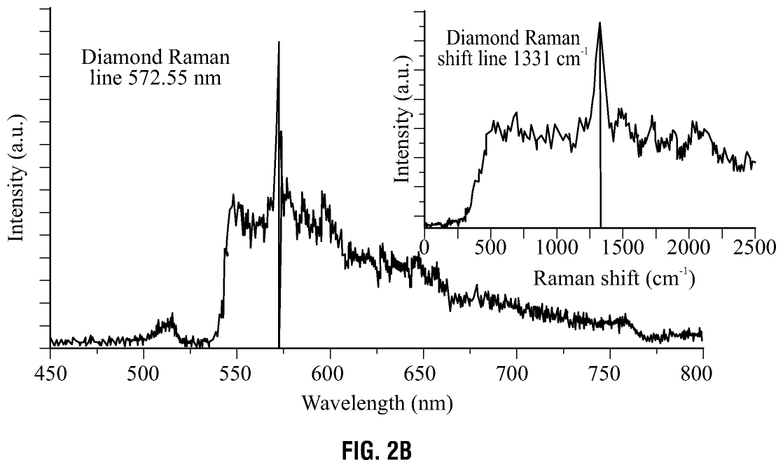

To determine if the electron beam in the TEM catalyzed the above growth, another growth was done in a vacuum tube furnace that did not have any electron beams. This was first done using a seeded growth mix that was further mixed with graphene flakes in solution. To investigate seeded growth in vacuum with graphene, two different seed molecules, with 1 nitrogen (N) and 2N atoms per seed (aza- and diaza-adamantane), as illustrated in FIG. 2(a), were used. FIG. 2(a) shows an illustration of the concept of seeded fluorescent nanodiamond growth using growth material mixed with graphene flakes on a quartz substrate in vacuum. The example shown includes an aza-adamantane seed molecule that could serve as a precursor for an NV color center and a diaza-adamantane seed that could be a precursor for an H3 center. The growth process includes adding a source that can produce reactive carbon, such as methyl and/or ethyl radicals, and then heating at vacuum. The reactive carbon can be supplied by cracking a hydrocarbon that decomposes at a much lower temperature than the diamond-like seed molecule. FIG. 2(b) shows an optical spectrum of grown nanodiamonds that reveals a clear and strong nanodiamonds Raman peak at 572 nm and Raman shift peak corresponding to the nanodiamonds. This spectrum was taken right after extracting the sample from the vacuum chamber. The temperature started at 400° C. while waiting a couple hours to see if seeded growth would take place. The temperature was raised to 800° C. for approximately 10-15 minutes to grow the diamonds larger. Without being bound by theory, it is believed that at this temperature, vacancies might enter the diamond and form color centers without irradiation or post-annealing. In this case, diamonds were observed with a distinct Raman line peaked at 572.55 nm and a 1331 cm⁻¹ Raman shift, as shown in FIG. 2(b). These samples were grown first on silicon and quartz wafers, and then in a quartz beaker to get larger quantities.

### Observations:

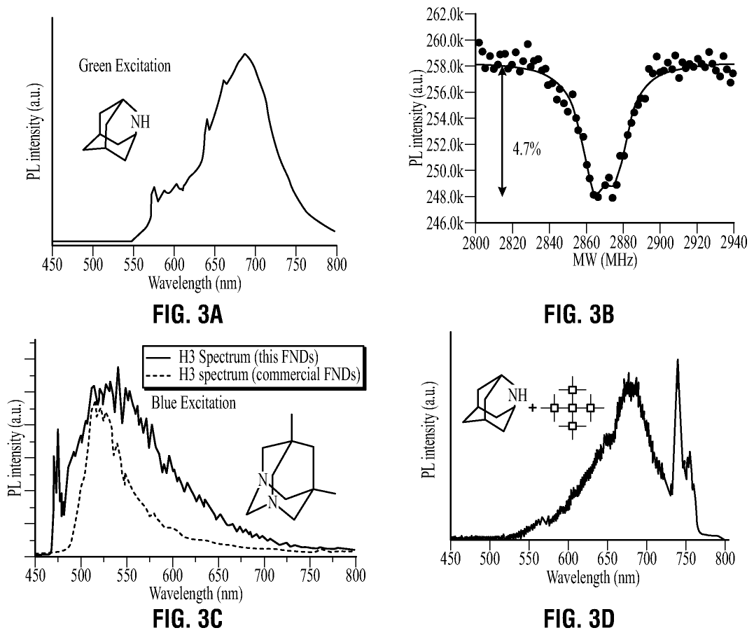

To prove that the above material is diamond, FIG. 3(a) shows a clear NV color center emission from the 1N seed mixture. To confirm the presence of the NV color center in the nanodiamonds, optically detected magnetic resonance (ODMR) techniques were performed for the NV center. FIG. 3(b) shows a clear ODMR spectrum with a good contrast equal to approximately 4.7%. Also, exclusively a color center, similar to H3, from the 2N seed without NV center emission (solid line), as illustrated in FIG. 3(c), was obtained (similar to high pressure growth at 400° C.), which indicates that the nanodiamonds have grown around the seed at lower temperatures (approximately 400° C.), and the vacancies moved close to the 2N atoms later on in the growth process at high temperature. The H3 color center spectrum is in approximate agreement with the H3 color center in commercial nanodiamonds excited at the same wavelength (471 nm) and previously published H3 color center spectrum. Furthermore, to again confirm diamond growth using this approach, a mixture of 2-azaadamantane hydrochloride seed and tetrakis(trimethylsilyl)silane seed with a Si/C atomic ratio of 0.07 in the initial mixture was utilized. Narrow silicon-vacancy (SiV) color center emission was observed and peaked at 738 nm with a width equal to approximately 6-7 nm from the 1N seed mixture along with the expected NV center emission as shown in FIG. 3(d). Notably, for high pressure growth the SiV emission in the tested nanodiamond crystals were not observed at these growth temperatures, as SiV needs a higher temperature during growth at high pressure, followed by irradiations and post annealing.

### Working Example 2

Time-lapse images of nanodiamonds growing on a heated stage inside a JOEL 2010 transmission electron microscope (TEM) at a temperature of 800° C. were collected. Diamond-like seed molecules and tetracosane were mixed at certain ratio and placed on a carbon TEM grid. This growth mixture was then heated to 800° C. on a heating stage inside the TEM microscope to grow diamond crystals. Several representative nanodiamond (ND) crystals were chosen for TEM diffraction imaging, which showed corresponding cubic diffraction spacing pattern for the representative ND crystals.

The images illustrated that the diamonds started at sizes that were barely visible and grew to as large as 200 nm. Ultra-small diamonds were present at 0 minutes due to the fact that the images could not be acquired until the temperature of the sample holder has stabilized for several minutes. The TEM grid was lacey carbon enhanced with graphene (Electron Microscopy Science EMS, USA). The growth medium consisted of the remnants of a mixture of alkanes which adhere to the TEM grid after pre-baking in air to 200° C. This baking process caused some agglomeration of the graphene flakes, but the grown diamonds are dispersed. To verify that the crystals formed by this process were cubic diamond, electron diffraction patterns of selected crystals were studied. The selected crystals exhibited bright diffraction at an angle that agrees with the (111) lattice spacing of cubic diamonds. It is important to note that most of the particles on the TEM grid are single crystals, with rounded or faceted shapes and smooth surfaces.

After growth, a small number of other particles were also found, some with strange shapes like rods and rectangles. These usually showed a diffraction pattern similar to graphite, although occasionally silicon carbide was also seen. Some crystals that displayed diffraction corresponding to the forbidden (200) diamond lattice spacing were also observed, which were previously reported in n-diamond. In fact, depending on growth conditions we can produce more or less of these diamond-like particles. However, in large crystals of this material we no longer see the (111) diffraction spots.

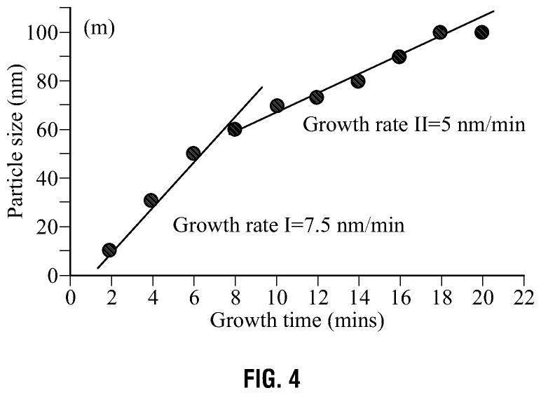

FIG. 4 is a graph of growth time in minutes versus particle size in nanometers. This graph is only for one representative particle. Two stages of growth process were observed characterized by two different growth rates. An initial growth rate over approximately the first 6 minutes of 7.5 nm/min was observed. A subsequent growth rate over approximately minutes 8 to 21 of 5 nm/min was observed. The average growth rate for the cubic nanodiamonds at 800° C. starts at about 5 nm/min but is not the same for all the diamonds, nor is it constant, as illustrated in FIG. 4. Presumably this is due to competition for the same growth material. This hypothesis is supported by the observation that the lower is the areal density of diamonds, the larger their average size. Eventually the growth rate for all the diamonds slows substantially, presumably due to depletion of the growth material. Finally, we note that the observed growth rate depends strongly on the type of particle. For example, graphite crystals grow much faster, completely consuming their growth material in about a minute. Silicon carbide is the next fastest growing. Significantly, the n-diamond-like particles grow at about the same rate as cubic diamond.

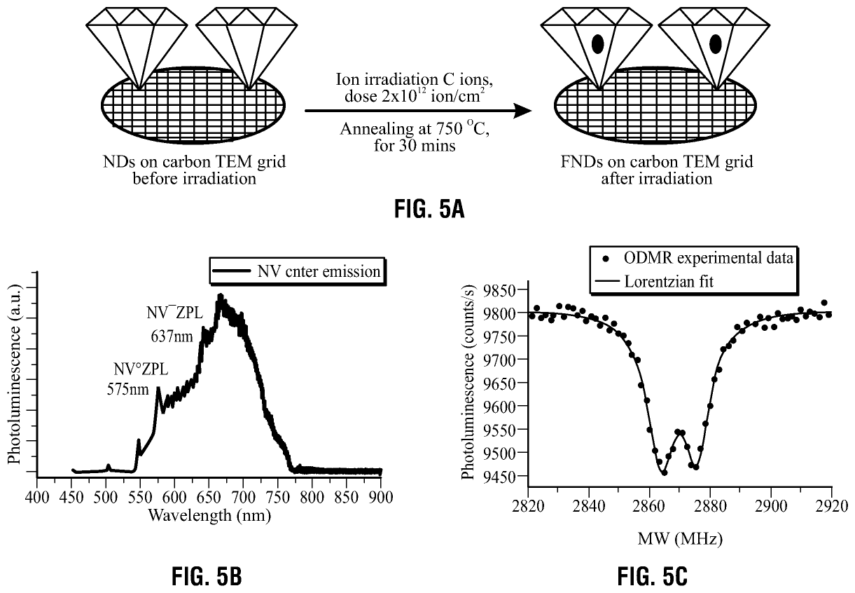

To further establish that the particles grown on the TEM grid in the time-lapse images are in fact cubic diamond, nitrogen-vacancy (NV) colors were produced in some of the samples. As the growth mix already contained nitrogen, it was only necessary to irradiate and anneal the diamonds. While can sometimes be done using the focused TEM electron beam and heated stage, we can only do this for a few crystals per hour. To process more crystals at a time, carbon implantation can be used to irradiate a large area. Specifically, carbon at 190 KeV energy was implanted at dose of 2×10¹² ion/cm², followed by annealing in vacuum at 750° C. for 30 minutes, as illustrated in FIGS. 5(a)-5(c).

After irradiation and annealing, the TEM grid was placed on a confocal laser scanning microscope, equipped with a spectrometer and microwave excitation (see method section). Using a green laser (532 nm, 200 uW), many bright fluorescent spots were found uniformly distributed on the TEM grid. The optical fluorescence spectra collected from most of these spots shows the signature of the NV center with NV0 and NV—zero-phonon lines peaked at 575 nm and 638 nm respectively, as illustrated in FIG. 5(b).

Even stronger proof of the presence of NV centers is provided by Optically Detected Magnetic Resonance (ODMR), as illustrated in FIG. 5(c). ODMR presents as a decrease in NV fluorescence when a microwave excitation is scanned over a ground state spin transition involving the m=0 and m=+/−1 levels in the triplet ground state. Typically, the fluorescence change is a maximum of about 30% for single NVs and 10% for ensembles, where this value is reduced to about half when there is a line splitting. FIG. 5(c) shows a typical ODMR spectrum from our TEM grid while the observed 3.6% contrast is slightly less than expected for NV ensembles with a line splitting, it can be explained by the strong autofluorescence background from the TEM grid.

Again experiments were done to investigate the high-energy electron beam of the TEM as a possible cause of the observed diamond growth. There have been reports of nanoparticles, including diamond, growing in situ under the influence of electron beam irradiation from the TEM. In fact, we find that amorphous carbon, presumably growth material, is attracted to the diamonds after prolonged electron irradiation at room temperature. However, we do not see a significant difference in crystal size or aerial density in the regions of the TEM grid that are not exposed to TEM irradiation.

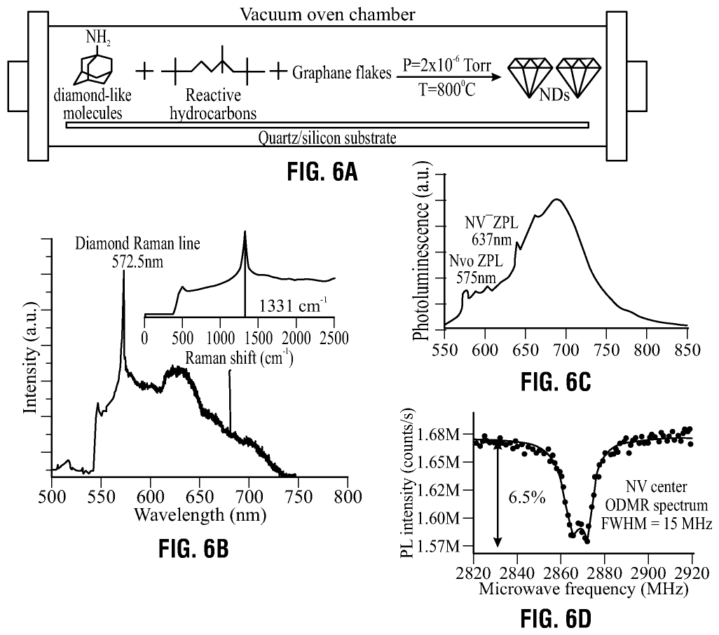

Nonetheless, to provide unequivocal verification that the electron beam is not responsible for diamond growth additional experiments were performed outside of the TEM. Specifically, some of the same growth material was deposited on a silicon chip and inserted into a custom-built vacuum tube furnace, as illustrated in FIG. 6(a). The furnace was then pumped down to a pressure of about 5×10⁻⁶ torr and heated up to 800° C. for 20-30 minutes. Initially, the growth material completely evaporated under these conditions, and no particles were found. To suppress this evaporation, a solution of single-layer graphene flakes were mixed into the growth medium. In a typical vacuum growth experiment, the temperature was first increased to 400° C. for 2-3 hours and while evaporation of volatile components of growth material was observed. When the pressure returned to about 5×10⁻⁶ torr, the temperature was then increased to 800° C. for about 20-30 minutes, and then finally returned to ambient.

After growth, the sample was optically investigated on the scanning confocal microscope. In areas where white growth product was found, the spectrum showed a distinct Raman line peaked at (572.55 nm or 1331 cm⁻¹), as seen in FIG. 6(b), which agrees with the Raman spectrum of diamond. Occasionally NV center emission was also observed (not shown), even though the sample was not yet irradiated. To increase the number of NVs, the silicon chip was irradiated and annealed following the same procedure described above for the TEM grid. After this, many spots in the optical scan showed a clear NV color center emission with NV0 and NV—zero-phonon lines peaked at 575 nm, and 637 nm respectively, as shown in FIG. 6(c). Again, to confirm the presence of the NV, optically detected magnetic resonance (ODMR) was performed. FIG. 6(d) shows the observed ODMR spectrum with a fluorescence contrast of 6.5%. The improved contrast, compared to the above TEM case, is due to eliminating background autofluorescence from the TEM grid.

To investigate whether graphene is needed for diamond growth in vacuum, the TEM growth was repeated using a grid consisting of an amorphous carbon membrane, but no graphene. Here, similar nanodiamond growth was observed. The presence of cubic diamond was again confirmed by the diffraction pattern. Hence, there is nothing special about graphene. Only that vacuum-evaporation of the heated growth material must somehow be suppressed. To confirm this hypothesis, growth on pure silicon (polycrystalline) TEM grids was investigated. In this case, no diamonds were observed, as in the case of silicon wafers growth without graphene. Finally, the vacuum growth was repeated using quartz wafers crucibles, which provided the same result as on the silicon wafer. Here the advantage of the crucible growth is that it is easy to produce much larger quantities of NDs.

Next the question of the quality of the vacuum-grown diamonds was investigated. For this, the NV center was used as a local probe of crystal quality. As seen in FIG. 6(d) the width of the NV ODMR spectrum is 15 MHz, which is typical for NV ensembles in highly nitrogen-doped, but otherwise high-quality bulk diamond. In particular, the zero-field splitting has recently been shown to be indicative of local electric fields caused to nitrogen impurities, rather than strain as previously assumed.

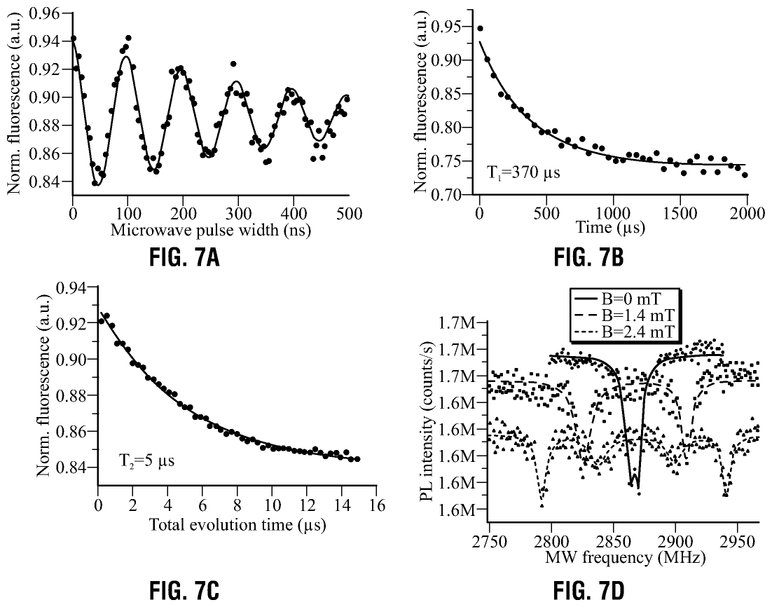

Additional measures of diamond quality are the NV spin longitudinal relaxation time T1 and spin coherence time T2. To measure these, Rabi oscillations measurements were first performed to determine the ability to coherently manipulate NV center's electronic ground spin state. FIG. 7(a) illustrates a clear Rabi oscillation between m_s=0 and m_s=±1 states of the NV center's ground state. The NV spin longitudinal relaxation time T1 and spin coherence time T2 were measured to be 370 μs and 5 μs respectively as shown in FIGS. 7(b) and 7(c). Interestingly, these values were significantly better than those reported in commercially available FNDs made by crushing HPHT crystals. Finally, as the NV center is typically used to sense important properties of samples quantities such as magnetic, electric fields and temperature, the ability of vacuum-grown diamond to sense different values of magnetic fields was demonstrated as shown in FIG. 7(d).

Finally, silicon-vacancy (SiV) color centers, in addition to NVs, were observed in some FNDs. Presumably the silicon impurity came from the silicon wafers. The corresponding ODMR spectrum of the NV center in those FNDs was noted and implied the possibility of growing FNDs with different desired color center depending on the diamond growth template.

### Growth Mix Preparation:

For both TEM and vacuum chamber experiments a diamond growth mixture with tetrahedral (diamond like) molecules such as 1-Adamantylamine, purity 97% (Sigma Aldrich, USA), and reactive hydrocarbons such as tetracosane (Sigma Aldrich >98%) was prepared. The mixing ratio was 20 μl of 1-Adamantylamine dissolved in dichloromethane (DCM) and 200 μl of reactive hydrocarbons (tetracosane). Also, 20 μl of 0.1 mg of graphene flakes dissolved in 1 ml of methanol (Electron Microscopy Science EMS, USA) was added to the vacuum chamber growth mixture. For diamond growth on TEM grid experiment, a few drops of the growth mixture without graphene flakes solution were dropped on a graphene-enhanced lacey carbon TEM (EMS inc. part #GF1201) and pure carbon film TEM grid (Ted Pella inc. part #1840) prior to experiments. For diamond growth experiment in vacuum chamber, a few drops from the growth mixture with graphene flakes solution were placed on quartz and silicon chips substrates prior to experiments.

### Irradiation and Annealing:

Most of the initial optical characterizations showed only diamond Raman line in NDs growing in TEM and vacuum chamber, but no NV center emission was detected. Therefore, post-irradiation and annealing was needed to produce the fluorescent color centers. So NDs on both TEM grid and silicon chip was irradiated by carbon ions with implantation energy 190 KeV at a dose of 2×10¹² ion/cm². After irradiation was completed samples were then annealed in vacuum at 750° C. for 30 minutes. Irradiation of NDs samples was done at a commercial irradiation facility (CuttingEdge Ions, LLC, USA).

### TEM Growth and Images:

A droplet of diamond growth mixture solution was placed on a carbon film TEM grid. These grids were heated in air to about 200° C. to remove most of the volatile components. Then grids were placed on a heating stage in a Joel 2010 TEM. Upon heating to 800° C. for 20 mins NDs crystals started to grow as demonstrated earlier in the text. NDs with sizes ranged from 10-120 nm showed a crystal lattice spacing near 2.06 A which matches diamond (111) spacing.

### Fluorescence and ODMR Spectra:

To analyze the fluorescence and optically detected magnetic resonance (ODMR) spectra of the fluorescence nanodiamonds (FNDs), a confocal laser scanning microscope was designed and built. The confocal microscope was equipped with high magnification microscope objective (100λ), multi-color lasers, and integrated microwave system. The FNDs samples were attached to a microwave board and placed on the confocal setup. Then, FNDs samples were scanned in x-y directions by green (532 nm) laser (max power=150 mW) using Thorlabs GVS 212 Galvano (10 mm mirrors) scanners. The fluorescence spectra was collected through the same microscope objective and analyzed with a custom-made spectrometer equipped with a starlight camera (Trius camera model SX-674), and a photon counter (Hamamatsu photon counter model number H7155-21). For the ODMR, the microwave (MW) frequencies were swept over a specific range (ex: 2700 MHz to 3000 MHz) and the fluorescent counts plotted vs MW frequency.

### Pulsed Measurements for T1 and T2 (Ulm):

Rabi oscillation measurements: a 1 μs green laser pulse polarizes the NV center and followed by microwave pulses, with varying time duration t, at fixed frequency (corresponding to the transition frequency between the m_s=0 and one of the m_s=±1 sub-levels). Finally, a green laser pulse will be applied to read out the NV center's state and record Rabi oscillation spectrum.

T1 measurements: we used a 1 μs laser pulse to optically polarize the NV center into the m_s=0 ground spin sublevel (3A2 state). And then, the NV defect is kept in the dark for a time τ, causing the system to relax towards a mixture of states m_s=0,±1. Finally, a second laser pulse was then applied to readout the final electron spin population and measure the NV center spin relaxation time (T1).

Han-echo measurements: From the Rabi oscillations spectrum, we determined the pulse durations of π/2 and π pulses needed for the subsequent Hahn-echo measurements. And then, following a first green initialization laser pulse, three resonant microwave pulses π/2−π−π/2 are applied. The NV center electron spin will accumulate a phase proportional to the amplitude of oscillating magnetic field acting along the NV center defect axis between these pulses. Finally, a second 518 nm laser pulse is then applied to readout the final spin state of the NV center at the end of the measurement.

The nanodiamonds growth conditions reported in this work agree with nanocrystalline diamond previously grown at atmospheric pressure except for the particle size limit. Prior work also pointed to the use of tetrahedral hydrocarbons including adamantane in the growth mix. Of interest then is why did the particles not spontaneously convert to graphite above the 7-13 nm size limit as in the previous work? We believe the answer to this question is the growth temperature. Although diamond is not the most stable form of carbon at atmospheric pressure, it is highly metastable with a lifetime of millions of years at ambient temperature. Therefore, to convert diamond into graphite it is necessary to overcome a barrier. In chemistry this is normally done with heat energy. It is well known that spontaneous conversion of bulk diamond to graphite occurs in vacuum at about 1700° C., sometimes explosively. However, in the case of diamond growth, a more relevant question is at what temperature does the diamond surface layer convert to graphite, since once this happens all subsequent growth will be graphite.

The answer to this question lies in surface reconstruction, since this process creates C═C double bonds that can serve as a graphite precursor. In vacuum, this takes place after hydrogen desorption, above a temperature of 900° C. Below 900° C., a hydrogen-terminated diamond surface has only sp3 carbon bonds that would presumably favor diamond growth. In fact, once the surface layer has reconstructed, the underlying diamond layers also slowly convert to graphite, which explains why nanoparticles larger than 7-15 nm do not have a diamond core remaining.

As H-terminated cubic diamond is the most stable form of carbon below 7 nm sizes, either self-seeding or seeding by diamond-like molecules, or even seeding by very small diamonds, would preferentially produce diamonds up to this size. As long as the growth temperature is kept below the surface reconstruction temperature of 900° C., the subsequent growth will continue to be cubic diamond. Note that a hydrogen-rich growth mix is also desired since atoms like oxygen catalyze the graphitization of diamond surfaces at temperatures as low as 400° C. Of course, if a graphite-like or non-cubic diamond seed crystal is present under these growth conditions, then subsequent growth would likely give a larger crystal of that same carbon form. This agrees with our observation of both diamond and graphite crystals growing on the same TEM grid.

### Working Example 3

Diamonds can grow at atmospheric pressure, even in the presence of small amounts of oxygen, provided the temperature is lower than ˜400° C. Such conditions are readily achievable in many chemistry laboratories and can be done with inexpensive glassware. We also demonstrate diamond growth at even lower temperatures, near 260° C., which can be accessed by a standard stove top of the type used for cooking. This has clear implications for future scalability.

Ultrasmall nanodiamonds below 15 nm (7 nm for cubic diamond) can be grown under low-oxygen conditions. However, larger nanodiamonds were shown to spontaneously convert into graphite. These results are in approximate agreement with theory that predicted hydrogen-terminated nanodiamond is the most stable form of carbon at any pressure, as long as the size is below 7 nm. Using methods of the instant disclosure, this size limit need not apply provided the growth temperature is kept below ˜900° C., where hydrogen termination remains intact and surface reconstruction does not take place. We note that other attempts were made to grow diamonds from organic hydrocarbons in inert atmosphere at a temperature of ˜1000° C. However, these methods mainly produced diamond-like carbon.

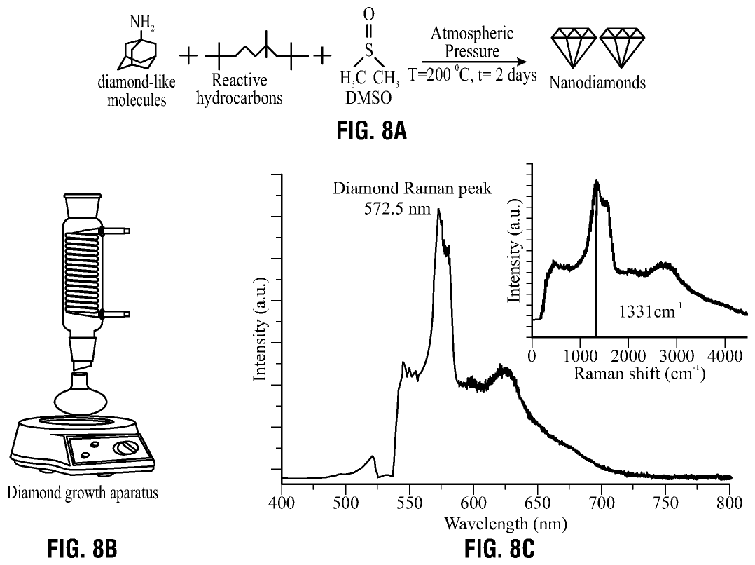

A mixture of diamond-template (or seed) molecules were mixed with easily cracked hydrocarbons. The seeds consisted of hydrogen-terminated polycyclic hydrocarbons, such as 1-admantylamine, and the hydrocarbons included heptamethylnonane, DMSO and tetracosane (see FIG. 8(a)). These growth mixtures were placed in a standard chemistry reflux system as shown in FIG. 8(b), sometimes in an inert nitrogen environment. The diamond growth experiments were carried out for growth times ranging from 24-72 hours and growth temperatures in range of 200−250° C. (as measured in the boiling liquid) or 350-400° C. while under nitrogen. Note that the polycyclic hydrocarbons are chemically stable until about ˜400° C. and therefore can serve as stable diamond growth templates at or below this temperature.

After the growth is complete, the heat was turned off and a sample of the growth mix was extracted for characterizations. Prior to optical characterizations, the sample was oxidized in air for 10 minutes at 550° C. to remove excess organic growth material, graphite and most of the diamond-like carbon (where applicable). The sample was placed on a confocal laser scanning microscope, where typically evidence of diamond is seen in the form of a distinct Raman line peaked at (572.55 nm and 1331 cm⁻¹ Raman shift) as shown in FIG. 8(c).

Additional sample investigations were then done with both scanning and transmission electron microscopes (SEM and TEM). The SEM and TEM images showed nanodiamonds with round shape and size ranging from 10-100 nm. Furthermore, the images showed crystalline, non-agglomerated nanoparticles (NPs) with sizes ranging from smaller than 10 nm to larger than 100 nm. The TEM diffraction pattern of these nanoparticles showed cubic diamond lattice spacing of (111). Most of the particles on the TEM grid, especially the round-shaped particles, showed the cubic diamond diffraction. But it is important to note that there were also particles with other shapes, especially rod and rectangle shapes, which usually showed graphite diffraction patterns.

The possibility of growing nanodiamonds from a variety of chemical combinations was also investigated, as illustrated in Table 1. As seen, 1-adamantaylamine dissolved in DMSO or DCM when added to long-chain hydrocarbons (heptamethylnonane and tetracosane) gave the largest amount of diamonds. In contrast, pure adamantane dissolved in DMSO gave the lowest amount of diamonds. While we do not know the reason for these variations, we are investigating whether the nitrogen-doped diamond template might produce thermionic electrons inside the growing diamond. Theory predicts that such electrons could eject radical H atoms from the diamond surface through dissociative electron attachment (DEA). These H radicals might then activate both the diamond surface and create hydrocarbon radicals in the growth mixture by H abstraction, allowing for continuous diamond growth.

TABLE 1
A summary of several nanodiamonds growth experiments using variety of diamond

| | | | | Diamond | |
|---|---|---|---|---|---|
| | Growth fuel | | | Raman peak | |
| | (hydrocarbon | Growth | Growth | position | Amount of |
| Diamond template | radicals) | temperature | time | (cm⁻¹) | diamonds |
| Adamantane | DMSO + | 220° C. | 24 h | 1350 | Very low |
| | heptamethylnonane | | | | |
| Adamantane | DMSO + | 400° C. | 24 h | 1350 | Moderate |
| | heptamethylnonane | (under | | | |
| | | nitrogen) | | | |
| 1- | DMSO + | 250° C. | 72 h | 1332 | High |
| Adamantylamine | heptamethylnonane | | | | |
| 1- | DCM + | 220° C. | 48 h | 1331 | High |
| Adamantylamine | heptamethylnonane | | | | |
| 1- | DCM + | 400° C. | 24 h | 1331 | High |
| Adamantylamine | heptamethylnonane | (under | | | |
| | | nitrogen) | | | |
| hexamethylenetetramine | DMSO + | 250° C. | 72 h | 1326 | Moderate |
| | heptamethylnonane | | | | |
| 1,3,5-Triaza-7- | DCM + | 220° C. | 48 h | 1331 | Moderate |
| phosphaadamantane | heptamethylnonane | | | | |
| 3-chloro-1- | DMSO + | 220° C. | 24 h | 1331 | High |
| aminoadamantane | Tetracosane | | | | |
| 3-chloro-1- | DCM + | 400° C. | 24 h | 1331 | Moderate |
| aminoadamantane | heptamethylnonane | (under | | | |
| | | nitrogen) | | | |
| Adamantane-1,3- | DCM + | 220° C. | 24 h | 1332 | Moderate |
| diamine | heptamethylnonane | | | | |

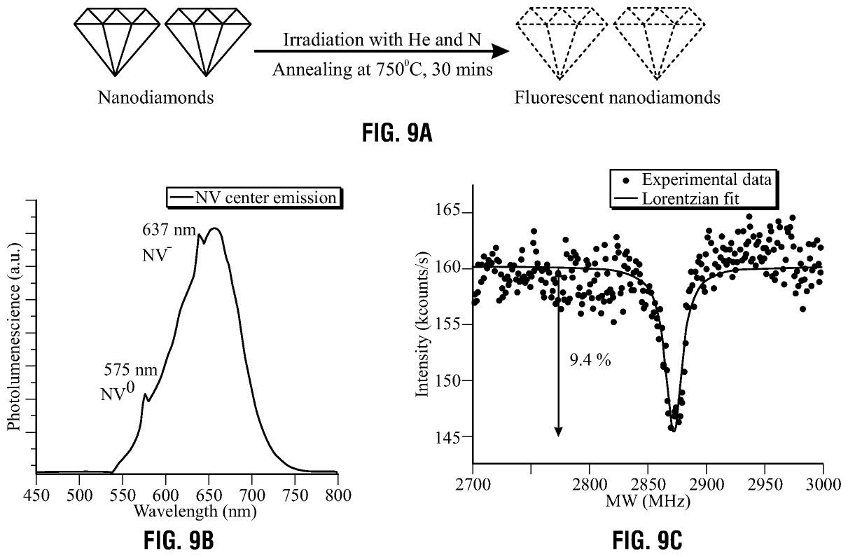

To provide additional evidence confirming the presence of cubic diamond, color centers like nitrogen-vacancy (NV) were created. The NV has well-known, unique magnetic properties, and is only known to exist in cubic diamond. For this purpose, the nanodiamond samples were co-implanted with helium and nitrogen. Ion irradiation was done at an energy of 190 KeV and different doses of 2×10¹² ion/cm² and 2×10¹³ ion/cm² for nitrogen and helium respectively. After that, a standard annealing at 750° C. for 30 minutes in vacuum was then performed to mobilize vacancies in the diamond crystals as illustrated in FIG. 9(a).

Next, to optically characterize the irradiated NDs, the sample was placed on a confocal laser scanning microscope equipped with spectrometer and a microwave excitation system. After scanning the TEM grid with a green laser (532 nm, 200 uW), we found some fluorescent spots. The optical fluorescence spectrum collected from each spot shows a clear spectrum of the NV center emission with NV0 and NV—zero-phonon lines peaked at 575 nm and 638 nm respectively as illustrated in FIG. 9(b). The presence of the NV centers was then confirmed by Optically Detected Magnetic Resonance (ODMR) as illustrated in FIG. 9(c). Briefly, ODMR in the NV is performed by first optically pumping the NV into the m_s=0 spin sublevel of the triplet ground state. A significant decrease of NV fluorescence results when a resonant microwave field induces a magnetic transition between the m_s=0 spin sublevel and the m_s=±1 levels. FIG. 9(c) demonstrates ODMR spectrum of the NV center with 9.4% contrast in our fluorescence nanodiamonds (FNDs). This relatively high ODMR contrast is evidence of good crystal quality.

In some embodiments, preparation of diamond growth material includes the following. Dimethylsulfoxide (DMSO) (ACS Reagent, 99.9%), Dichloromethane (DCM) (ACS Reagent, 99.5%), (2,2,4,4,6,8,8-Heptamethylnonane (HMN) (98%), Tetracosane (99%) were purchased from Sigma Aldrich (St. Louis, Mo., USA). 10 mls of either DMSO or DCM were placed in a 50 ml beaker containing a stir bar. 100 mgs of seed molecule were then added to the solution and the beaker was covered with a watch glass and placed on a heated stir plate. The sample was stirred until completely dissolved. Some seed molecules require a small amount of heat to completely dissolve. Once in solution the sample was transferred to a round-bottom flask containing either 2 mls of HMN or 200 mgs of Tetracosane. The round bottom was closed off with a reflux condenser, placed in a heating mantle and the temperature brought to 200-250° C. A thermocouple was placed between the round bottom flask and the heating mantle to measure the external temperature. While refluxing with DMSO, tap water was used as the coolant, however with DCM a circulating chiller was attached to the reflux condenser and a solution of antifreeze and water was used to cool the condenser to 0° C. The reaction was allowed to reflux at temperature until the desired time was reached, 24-72 hours, at which point the heating was turned off and the sample was allowed to cool to room temperature. Once at room temperature the sample was extracted and stored in glass vials at room temperature.

In some embodiments, preparation of the diamond growth includes the following, 10 mls of DCM was placed in a 50 ml beaker containing a stir bar, 100 mgs of seed molecule were then added to the solution, the beaker covered with a watch glass and placed on a heated stir plate. The Sample was stirred until completely dissolved. Some seed molecules require a small amount of heat to completely dissolve. Once in solution the sample was transferred to a quartz round-bottom flask containing either 2 mls of HMN or 200 mgs of Tetracosane. The round bottom was closed off with a reflux system and the top of the reflux was closed off with an adapter for Schlenk line. A thermocouple was placed between the round bottom flask and the heating mantle to measure the external temperature. The system was first purged of air using a vacuum then rinsed with pure argon gas, this rinse procedure was repeated a total of 4 times to remove any oxygen from the reaction container. Finally a constant supply of nitrogen gas was allowed to flow over the reaction and out through an oil bubbler which allows an inert gas blanket at atmospheric pressure. Refluxing was performed using a recirculating chiller containing a antifreeze and water mixture to bring the temperature to 0° C. The temperature of the mantle was then brought to 400° C. and allowed to react under inert gas and refluxing for 24 hours, at which point the heating was turned off and the temperature was allowed to cool to room temperature. Once at room temperature the sample was extracted and stored in glass vials at room temperature.

In some embodiments, preparation for confocal imaging includes the following. Quartz slides were first rinsed with acetone to remove any oils and dirt, the slides were then placed on a heating plate inside of a fume hood. Samples prepared in the stove top procedure were then dropped onto the slide using a transfer pipette and the temperature was raised to 200° C. for DMSO, or 50° C. for HMN. Once the samples were completely dry they were placed in a tube furnace set to 550° C. and allowed to oxidize for 10 minutes. After 10 minutes the samples were removed and cooled to room temperature before being placed on the confocal. Each sample was then analyzed for Raman shift using a 532 nm laser.

Observations

We have experimentally demonstrated growth of high-quality single-crystal cubic diamonds in vacuum, both in a furnace and in situ on TEM grids. Evidence of diamond formation appears in electron diffraction data, the optical Raman spectra, and the optical fluorescence spectra of nitrogen-vacancy (NV). In addition, optically detected magnetic resonance (ODMR) data provides the key signature that proves that the crystals are not any other form of carbon.

We also used the NVs to probe the quality of our vacuum-grown diamond and found it comparable to bulk diamonds, with similar nitrogen concentration, grown by either HPHT or CVD. In addition, the smooth morphology of the vacuum-grown nanodiamonds makes them especially well-suited for bio-sensing applications.

We have experimentally developed simple, inexpensive, and highly-scalable diamond growth technique, which can even be implemented on a standard top-stove of the type used for cooking. This growth technique does not require any pressure chamber, and is even compatible with small amounts of oxygen, such as from the air or solvents in the growth mix. The diamond growth was confirmed using SEM, TEM, and optical characterizations. As additional proof, the diamonds were made fluorescent after suitable irradiation and annealing. The result was Nitrogen-Vacancy color centers showing a high contrast and splitting-free ODMR spectrum which is an indication of high-quality diamond. This innovative diamond growth technique holds promise for virtually any industrial application of diamond that can benefit from highly scalable, low-cost growth. The resulting diamond are also of sufficiently good quality for demanding applications like quantum information and biology.

The unprecedented growth of diamonds to sizes much larger than the thermodynamic limit, suggests that there is no ultimate size limit to our diamond vacuum-growth. Therefore, this work opens the door to growing diamonds in large quantities, without expensive high-pressure or plasma (CVD) growth chambers. Future work includes growth of diamonds at pressures higher than vacuum, especially atmospheric pressure, where scaling up to larger quantities is simplified.

Although various embodiments of the present disclosure have been illustrated in the accompanying Drawings and described in the foregoing Detailed Description, it will be understood that the present disclosure is not limited to the embodiments disclosed herein, but is capable of numerous rearrangements, modifications, and substitutions without departing from the spirit of the disclosure as set forth herein.

The term “substantially” is defined as largely but not necessarily wholly what is specified, as understood by a person of ordinary skill in the art. In any disclosed embodiment, the terms “substantially,” “approximately,” “generally,” and “about” may be substituted with “within [a percentage] of” what is specified, where the percentage includes 0.1, 1, 5, and 10 percent.

The foregoing outlines features of several embodiments so that those skilled in the art may better understand the aspects of the disclosure. Those skilled in the art should appreciate that they may readily use the disclosure as a basis for designing or modifying other processes and structures for carrying out the same purposes and/or achieving the same advantages of the embodiments introduced herein. Those skilled in the art should also realize that such equivalent constructions do not depart from the spirit and scope of the disclosure, and that they may make various changes, substitutions, and alterations herein without departing from the spirit and scope of the disclosure. The scope of the invention should be determined only by the language of the claims that follow. The term “comprising” within the claims is intended to mean “including at least” such that the recited listing of elements in a claim are an open group. The terms “a,” “an,” and other singular terms are intended to include the plural forms thereof unless specifically excluded.

1-43. (canceled)

44. A method for low-pressure diamond growth, the method comprising:
heating a composition comprising a source of reactive carbon to a temperature below 800° C. where diamond does not spontaneously convert to graphite, wherein the heating takes place at a pressure below 1 GPa where diamond is not the most stable form of carbon; and
responsive to the heating, growing diamonds from the composition,
wherein the composition comprises a catalyst that enhances a growth rate or a nucleation efficiency of the diamonds; and
wherein the catalyst comprises a sheet or a powder of nanoporous material that binds growth material by physisorption or chemisorption.

45. The method of claim 44, wherein the source of reactive carbon comprises an organic molecule that comprises carbon and hydrogen and that begins to decompose at a growth temperature of the diamonds.

46. The method of claim 44, wherein the source of reactive carbon comprises long-chain branched or unbranched alkanes or alkenes, waxes, light or heavy oils, polymers, paraffin, tetracosane, heptamethylnonane, or any combination thereof.

47. The method of claim 44, wherein the composition comprises a seed crystal or a seed molecule that serves as a diamond growth template or as a precursor for a fluorescent color center, or any combination thereof.

48. The method of claim 47, wherein the seed crystal comprises a hydrogen-terminated diamond surface or a hydrogen-terminated diamond surface that is functionalized with atomic or molecular groups that serve as precursors for fluorescent color centers, or any combination thereof.

49. The method of claim 47, wherein the seed molecule comprises a diamond-like organic molecule that can be substituted or functionalized with atomic or molecular groups that serve as precursors for fluorescent color centers, or any combination thereof.

50. The method of claim 47, wherein the seed molecule comprises a diamondoid or diamondoid derivative, or any combination thereof.

51. The method of claim 47, wherein the seed molecule comprises a diamondoid functionalized with amines, halogens, sulfur, hydroxide, metals, or other atoms that serve as precursors for diamond color centers

52. The method of claim 47, wherein the seed molecule is selected from the group consisting of aza-adamantane, diaza-adamantane, adamantyl-amine, and adamantyl-diamine.

53. The method of claim 47, wherein the composition comprises a solvent that increases solubility of the seed molecule.

54. The method of claim 53, wherein the solvent comprises halogenated hydrocarbons, aminated hydrocarbons, thiolated hydrocarbons, alcohols, or other strong solvents, or any combination thereof.

55. The method of claim 53, wherein the solvent comprises dichloromethane, chlorobenzene, trichloroethylene, dimethylsulfoxide, acetonitrile, isopropopyl alcohol, or any combination thereof.

56. A method for low-pressure diamond growth, the method comprising:
heating a composition comprising a source of reactive carbon to a temperature below 800° C. where diamond does not spontaneously convert to graphite, wherein the heating takes place at a pressure below 1 GPa where diamond is not the most stable form of carbon;
responsive to the heating, growing diamonds from the composition,
wherein the composition comprises a seed crystal that serves as a diamond growth template or as a precursor for a fluorescent color center; and
wherein the seed crystal is a hydrogen-terminated diamond surface or a hydrogen-terminated diamond surface that is functionalized with atomic or molecular groups that serve as precursors for fluorescent color centers, or any combination thereof.

57. The method of claim 56, wherein the source of reactive carbon comprises an organic molecule that comprises carbon and hydrogen and that begins to decompose at a growth temperature of the diamonds.

58. The method of claim 56, wherein the source of reactive carbon comprises long-chain branched or unbranched alkanes or alkenes, waxes, light or heavy oils, polymers, paraffin, tetracosane, heptamethylnonane, or any combination thereof.

59. The method of claim 56, wherein the seed crystal comprises a hydrogen-terminated diamond surface or a hydrogen-terminated diamond surface that is functionalized with atomic or molecular groups that serve as precursors for fluorescent color centers, or any combination thereof.

60. A method for low-pressure diamond growth, the method comprising:
heating a composition comprising a source of reactive carbon to a temperature below 800° C. where diamond does not spontaneously convert to graphite, wherein the heating takes place at a pressure below 1 GPa where diamond is not the most stable form of carbon; and
responsive to the heating, growing diamonds from the composition,
wherein the composition comprises a catalyst that enhances a growth rate or a nucleation efficiency of the diamonds; and
wherein the catalyst comprises an amorphous carbon film, graphene flakes, or graphite particles, or any combination thereof.

61. The method of claim 60, wherein the source of reactive carbon comprises an organic molecule that comprises carbon and hydrogen and that begins to decompose at a growth temperature of the diamonds.

62. The method of claim 60, wherein the source of reactive carbon comprises long-chain branched or unbranched alkanes or alkenes, waxes, light or heavy oils, polymers, paraffin, tetracosane, heptamethylnonane, or any combination thereof.

63. The method of claim 60, wherein:
the composition comprises a solvent that increases solubility of the seed molecule; and
the solvent comprises halogenated hydrocarbons, aminated hydrocarbons, thiolated hydrocarbons, alcohols, or other strong solvents, or any combination thereof.
